(19) United States
(12) Patent Application Publication
(10) Pub. No.: US 2014/0197410 A1
(43) Pub. Date: Jul. 17, 2014

(54) Semiconductor Structure and Method for Manufacturing the Same

(71) Applicants: Haizhou Yin, Poughkeepsie, NY (US); Huilong Zhu, Poughkeepsie, NY (US); Zhijiong Luo, Poughkeepsie, NY (US)

(72) Inventors: Haizhou Yin, Poughkeepsie, NY (US); Huilong Zhu, Poughkeepsie, NY (US); Zhijiong Luo, Poughkeepsie, NY (US)

(21) Appl. No.: 13/697,096

(22) PCT Filed: May 17, 2012
(86) PCT No.: PCT/CN2012/000679

§ 371 Date: Nov. 9, 2012

(30) Foreign Application Priority Data
Jun. 20, 2011 (CN) 201110166510.2

(51) Int. Cl. H01L 29/78; H01L 29/66; H01L 29/04

(52) U.S. Cl. CPC H01L 29/78; H01L 29/04; H01L 29/66477
USPC 257/57; 438/151; 257/347; 257/66

(57) ABSTRACT

The present invention provides a method for manufacturing a semiconductor structure. The method comprises: providing an SOI substrate and forming a gate structure on said SOI substrate; etching a SOI layer and a BOX layer of the SOI substrate on both sides of the gate structure to form a trench exposing the BOX layer, said trench partially entering into the BOX layer; forming a stressed layer that fills up a part of said trench; forming a semiconductor layer covering the stressed layer in the trench. Correspondingly, the present invention also provides a semiconductor structure formed by the above method. In the semiconductor structure and the method for manufacturing the same according to the present invention, a trench is formed on an ultrathin SOI substrate, first filled with a stressed layer, and then filled with a semiconductor material to be ready for forming a source/drain region. The stressed layer provides a favorable stress to the channel of the semiconductor device, thus facilitating improving the performance of the semiconductor device.

### CROSS-REFERENCE TO RELATED APPLICATION

This application is a National Stage application of, and claims priority to, PCT Application No. PCT/CN2012/000679, filed on May 17, 2012, entitled “Semiconductor Structure and Method for Manufacturing the same”, which claimed priority to Chinese Application No. 201110166510.2, filed on Jun. 20, 2011. Both the PCT Application and Chinese Application are incorporated herein by reference in their entireties.

### FIELD OF THE INVENTION

The present invention relates to the field of semiconductor fabrication, and in particular, to a semiconductor structure and a method for manufacturing the same.

### BACKGROUND OF THE INVENTION

With the development in the technique of manufacturing semiconductor structures, integrated circuits with better performance and stronger function require a higher density of elements, meanwhile, the space between the components or elements or the dimension, size and space of each element per se need to be further reduced (currently, it has been reduced to a nanometer level). With the reduction in the size of the semiconductor device, various microeffects emerge, so in order to meet the requirements of device development, those skilled in the art have always been actively exploring new manufacturing processes.

An important factor for maintaining the performance of a field effect transistor is the carrier mobility. When a voltage is applied to a gate that is isolated from the channel by a very thin gate dielectric, the carrier mobility may affect the amount of current or charges flowing in the doped semiconductor channel.

The mechanical stress in the channel region of an FET (Field Effect Transistor) can notably increase or decrease the carrier mobility according to the type and the stress direction of the carrier. In the FET, a tensile stress can increase the electron mobility and advantageously improve the performance of the NMOS(N-type Metal Oxide Semiconductor) device, while a compressive stress can increase the hole mobility and advantageously improve the performance of the PMOS (P-type Metal Oxide Semiconductor) device.

In the existing process of manufacturing a semiconductor device using an ultrathin SOI substrate, the SOI layer and BOX layer of part of the SOI substrate are etched and then filled with a semiconductor material to be ready for forming a source/drain region. However, the stress provided by the filled semiconductor material is limited, so the favorable stress applied to the channel region of the semiconductor device is also limited, which cannot effectively improve the operating performance of the semiconductor device.

### SUMMARY OF THE INVENTION

An object of the present invention is to provide a semiconductor structure and a method for manufacturing the same, in which a favorable stress is introduced into a channel region of a semiconductor device that is manufactured using an ultrathin SOI substrate by burying a stress layer, thereby improving the performance of the semiconductor device.

According to one aspect, the present invention provides a method for manufacturing a semiconductor structure, which comprises:

a) providing an SOI substrate and forming a gate structure on the SOI substrate;
b) etching a SOI layer and a BOX layer of the SOI substrate on both sides of the gate structure to form a trench exposing the BOX layer, the trench partially entering into the BOX layer;
c) forming a stressed layer by filling up a part of said trench; and
d) forming a semiconductor layer to cover the stressed layer in the trench.

According to another aspect, the present invention also provides another method for manufacturing a semiconductor structure, which comprises:

a) providing an SOI substrate and covering a part of said SOI substrate with a mask, the part of said SOI substrate covered by the mask being the area that is predetermined for forming a gate line;
b) etching a SOI layer and a BOX layer of the SOI substrate on both sides of the mask to form a trench exposing the BOX layer, the trench partially entering into the BOX layer;
c) forming a stressed layer by filling up a part of said trench;
d) forming a semiconductor layer to cover the stressed layer in the trench; and
e) removing the mask to expose the part of said SOI substrate covered by the mask and forming a gate structure thereon.

Correspondingly, the present invention also provides a semiconductor structure, which comprises an SOI substrate, a gate structure, a stressed layer and a semiconductor layer, wherein

the SOI substrate includes a SOI layer and a BOX layer;
the gate structure is formed on the SOI layer;
the stressed layer is formed in the SOI substrate on both sides of the gate structure to contact the BOX layer and extend into the BOX layer, and the upper surface of the stressed layer is lower than the lower surface of the gate structure; and
the stressed layer (160) is covered by the semiconductor layer (150) and the semiconductor layer (150) is in contact with the SOI layer (100).

In the semiconductor structure and the method for manufacturing the same according to the present invention, a trench is formed on an ultrathin SOI substrate, first filled with a stressed layer, and then filled with a semiconductor material to be ready for forming a source/drain region. The stressed layer provides a favorable stress to the channel of the semiconductor device, thus facilitating improving the performance of the semiconductor device.

### BRIEF DESCRIPTION OF THE DRAWINGS

Other features, objects and advantages of the present invention will become more apparent by reading the detailed descriptions of the non-limiting embodiments taken with reference to the following accompanying drawings, in which:

FIGS. 1(a) and 1(b) are flow charts of two specific embodiments of the method for manufacturing the semiconductor structure according to the present invention;

FIGS. 2-6 are schematic cross-sectional views of the various manufacturing stages of the semiconductor structure during the process for manufacturing the semiconductor structure following the flow as shown in FIG. 1(a) according to one specific embodiment of the present invention; and FIGS. 7-9 are schematic cross-sectional views of the various manufacturing stages of the semiconductor structure during the process for manufacturing the semiconductor structure following the flow as shown in FIG. 1(b) according to one specific embodiment of the present invention.

In the drawings, the same or similar reference numbers indicate the same or similar components.

### DETAILED DESCRIPTION OF THE PREFERRED EMBODIMENTS

In order to make the objects, technical solutions and advantages of the present invention clearer, the embodiments of the present invention will be described in detail below with reference to the drawings.

The embodiments of the present invention will be described in detail below, and examples of the embodiments are shown in the figures. Throughout the drawings, the same or similar reference numbers represent the same or similar elements or elements having the same or similar functions. The embodiments described below with reference to the drawings are exemplary, which are only for illustrating the present invention instead of limiting the present invention.

The following disclosure provides a plurality of different embodiments or examples to achieve different structures of the present invention. To simplify the disclosure of the present invention, description of the components and arrangements of specific examples is given below. Of course, they are only illustrative and not intended to limit the present invention. Moreover, in the present invention, reference numbers and/or letters may be repeated in different embodiments. Such repetition is for the purposes of simplification and clearness, and does not denote the relationship between respective embodiments and/or arrangements being discussed. In addition, the present invention provides various examples for specific process and materials. However, it is obvious for a person of ordinary skill in the art that other process and/or materials may alternatively be utilized. Furthermore, the following structure in which a first object is “on” a second object may include an embodiment in which the first object and the second object are formed to be in direct contact with each other, and may also include an embodiment in which another object is formed between the first object and the second object such that the first and second objects might not be in direct contact with each other.

The semiconductor structure provided by the present invention has several preferred structures, and one of the preferred structures will be chosen to be described as an example.

### Embodiment 1

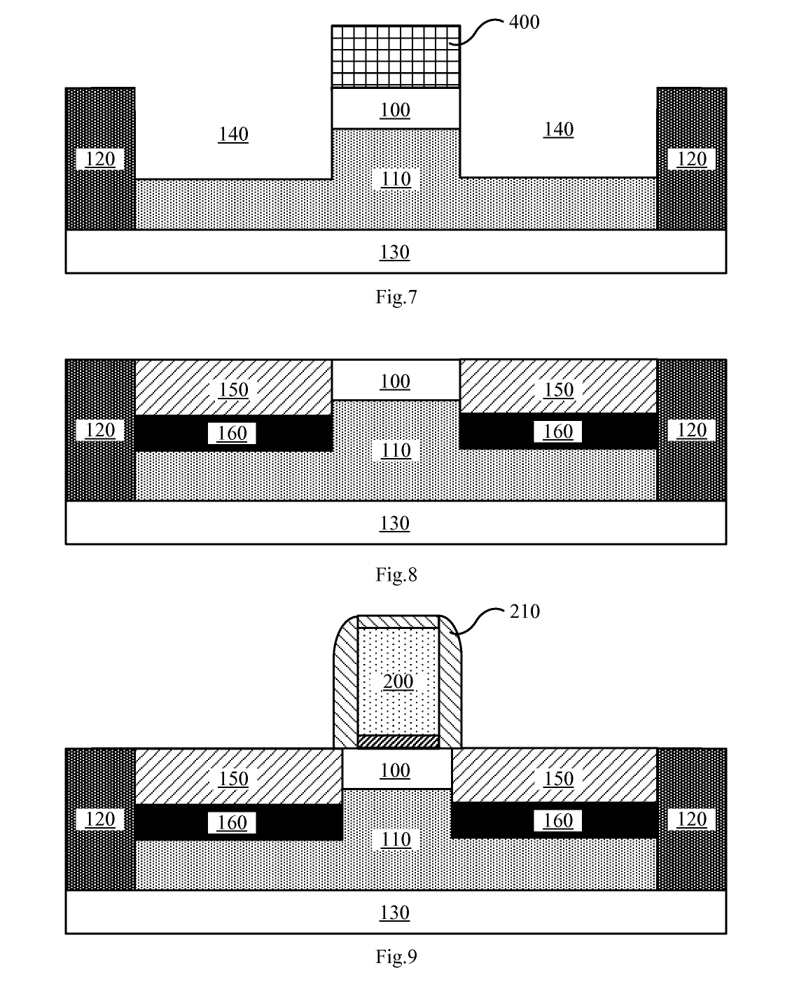

Reference is now made to FIG. 6, which shows a semiconductor structure. The semiconductor structure comprises an SOI substrate, a gate structure 200, a stressed layer 160 and a semiconductor layer 150, wherein

the SOI substrate comprises a SOI layer 100 and a BOX layer 110;
the gate structure 200 is formed above the SOI layer 100;
the stressed layer 160 is formed in the SOI substrate on both sides of the gate structure 200, is in contact with the BOX layer 110 and extends into the BOX layer 110, and the upper surface of the stressed layer 160 is lower than the lower surface of the gate structure 200; and
the semiconductor layer 150 covers the stressed layer (160) and is in contact with the SOI layer 100.

In addition, sidewall spacers 210 are formed on both sides of the gate structure 200.

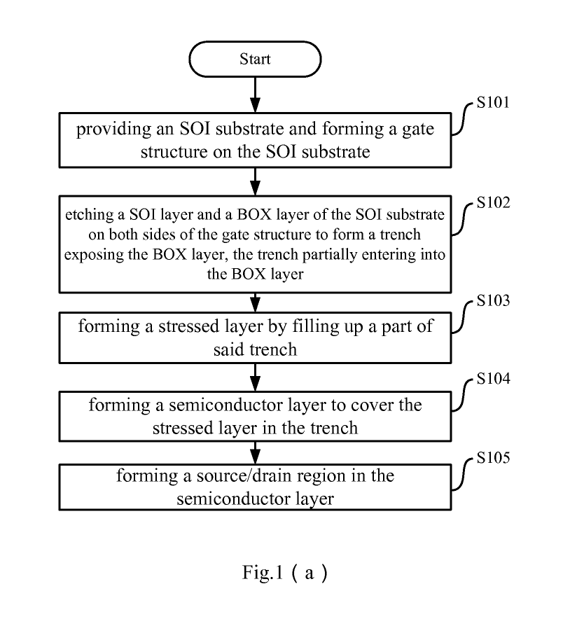

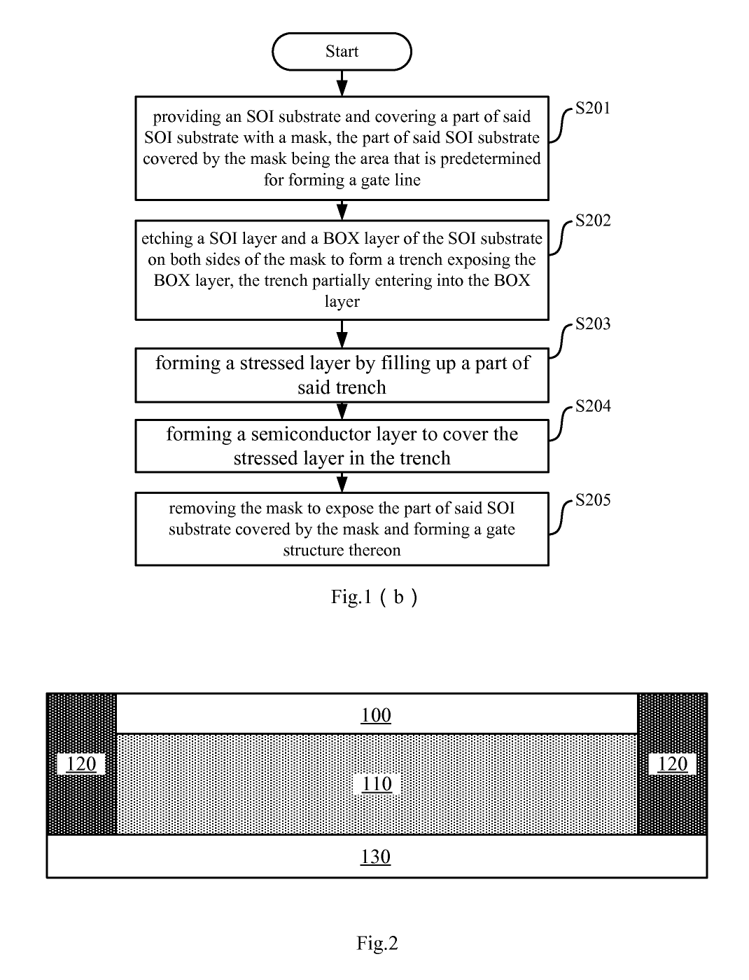

The SOI substrate has at least a structure of three layers, which is comprised of a bulk silicon layer 130 (only a part of the bulk silicon layer 130 is shown in FIG. 1), the BOX layer 110 on the bulk silicon layer 130, and the SOI layer 100 overlaying the BOX layer 110. The material of the BOX layer 110 usually uses SiO₂, and the thickness of the BOX layer is usually greater than about 100 nm. The material of the SOI layer 100 may be monocrystalline silicon, Ge, or group III-V compounds, such as SiC, gallium arsenide, indium arsenide or indium phosphide, etc. The SOI substrate used in this specific embodiment is an SOI substrate having an ultrathin SOI layer 100, so the thickness of the SOI layer 100 is usually smaller than about 100 nm, e.g. 50 nm. Usually an isolation region 120 is also formed in the SOI substrate for dividing the SOI layer 100 into separate regions so as to be used for forming the transistor structures in subsequent processing. The material of the isolation region 120 is an insulating material, which may be, for example, SiO₂ or Si₃N₄, or any combination thereof. The width of the isolation region 120 may be determined according to the design requirement of the semiconductor structure.

In a gate-first process, the gate structure 200 comprises a gate dielectric layer and a gate stack, while in a gate-last process, the gate structure 200 comprises a dummy gate and a gate dielectric layer carrying the dummy gate. The sidewall spacer 210 may be formed of silicon nitride, silicon oxide, silicon oxynitride, silicon carbide and/or other appropriate materials. The sidewall spacer 210 may have a multi-layered structure. The sidewall spacer 210 may be formed by a deposition-etching process, and the thickness of the sidewall spacer 210 is within the range of about 10 nm to 100 nm.

The material of the stressed layer 140 may be silicon nitride. In this embodiment, the stressed layer 140 may be also in contact with the isolation region 120. Preferably, the thickness of the stressed layer 140 is smaller than the thickness of the semiconductor layer 150. In another preferred embodiment, the thickness of the stressed layer 140 is smaller than about 50 nm.

The material of the semiconductor layer 150 may be one of polysilicon, amorphous silicon, silicon-germanium, and amorphous silicon-germanium, or any combination thereof. The upper surface of the semiconductor layer 150 may be flush with the lower surface of the gate structure 200 by means of a planarization processing. The semiconductor layer 150 is not only in contact with the SOI layer 100 but also in contact with the isolation region 120. The thickness of the semiconductor layer 150 is usually within the range of about 50 nm to 150 nm.

Alternatively, a source/drain region has already been formed in the semiconductor layer 150. For example, for a PMOS device, the source/drain region may be a P-doped SiGe, and for a NMOS device, the source/drain region may be a N-doped Si.

It shall be noted that, there is not only the semiconductor structure provide by the above embodiment 1 but also other semiconductor structures in the same semiconductor device according to the design requirement.

The above embodiment will be further described in conjunction with the method for manufacturing the semiconductor structure provided by the present invention.

Referring to FIG. 1(a), which is a flow chart of a specific embodiment of the method for manufacturing the semiconductor structure according to the present invention. The method comprises:

step S101: providing an SOI substrate and forming a gate structure on the SOI substrate;
step S102: etching the SOI layer and the BOX layer of the SOI substrate on both sides of the gate structure to form a trench exposing the BOX layer, the trench partially entering into the BOX layer;
step S103: forming a stressed layer that fills up a part of the trench; and
step S104: forming a semiconductor layer covering the stressed layer in the trench.

The steps S101 to S104 will be described below with reference to FIGS. 2-6. FIGS. 2-6 are schematic cross-sectional views of the various manufacturing stages of the semiconductor structure during the process for manufacturing the semiconductor structure following the flow as shown in FIG. 1(a) according to one specific embodiment of the present invention. It shall be noted that the drawings for each of the embodiments of the present invention are only schematic, and thus are not drawn to scale.

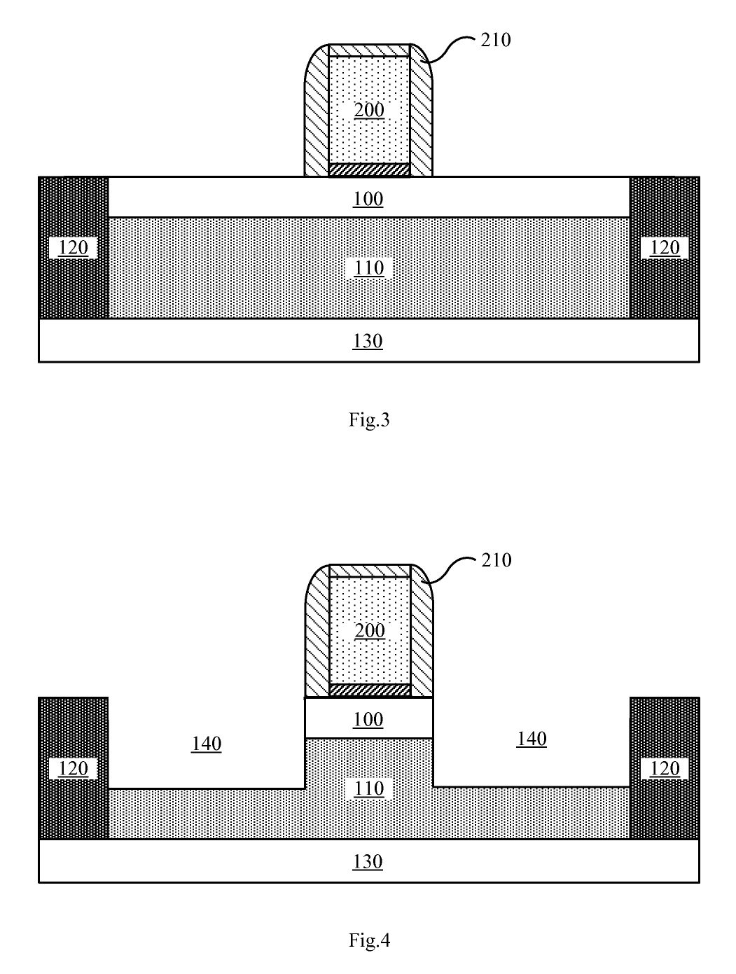

Referring to FIGS. 2 and 3, step S101 is performed to provide an SOI substrate and to form a gate structure 200 on the SOI substrate.

First, referring to FIG. 2, the SOI substrate has at least a structure of three layers, which is comprised of a bulk silicon layer 130 (only a part of the bulk silicon layer 130 is shown in FIG. 1), a BOX layer 110 on the bulk silicon layer 130, and an SOI layer 100 overlaying on the BOX layer 110. The material of the BOX layer 110 usually uses SiO₂, and the thickness of the BOX layer is usually greater than about 100 nm. The material of the SOI layer 100 may be monocrystalline silicon, Ge, or group III-V compound, such as SiC, gallium arsenide, indium arsenide or indium phosphide, etc. The SOI substrate used in this specific embodiment is an SOI substrate having an ultrathin SOI layer 100, so the thickness of the SOI layer 100 is usually smaller than about 100 nm, e.g. 50 nm. Usually an isolation region 120 is also formed in the SOI substrate for dividing the SOI layer 100 into separate regions so as to be used for forming the transistor structures in subsequent processing. The material of the isolation region 120 is an insulating material, which may be, for example, SiO₂ or Si₃N₄, or a combination thereof. The width of the isolation region 120 may be determined according to the design requirement of the semiconductor structure.

Then referring to FIG. 3, a gate structure 200 is formed on the SOI substrate, specifically on the SOI layer 100. In a gate-first process, the procedure for forming the gate structure 200 includes the following steps of: forming a gate dielectric layer covering the SOI layer 100 and the isolation region 120, a gate metal layer covering the gate dielectric layer, a gate electrode layer covering the gate metal layer, an oxide layer covering the gate electrode layer, a nitride layer covering the oxide layer, and a photoresist layer covering the nitride layer and being patterned to etch a gate stack. The material of the gate dielectric layer may be a thermal oxide layer that includes silicon oxide and silicon oxynitride, or a high-K dielectric, such as one of HfO₂, HfSiO, HfSiON, HfTaO, HfTiO, HfZrO, Al₂O₃, La₂O₃, ZrO₂, LaAlO or any combination thereof, and the thickness of the gate dielectric layer may be between about 1 nm to 4 nm. The material of the gate metal layer may be one of TaC, TiN, TaTbN, TaErN, TaYbN, TaSiN, HfSiN, MoSiN, RuTaₓ, NiTa or any combination thereof, and the thickness of the gate metal layer may be between about 5 nm to 20 nm. The material of the gate electrode layer may be Poly-Si, and the thickness of the gate electrode layer may be between about 20 nm to 80 nm. The material of the oxide layer may be SiO₂, and the thickness of the oxide layer may be between about 5 nm to 10 nm. The material of the nitride layer may be Si₃N₄, and the thickness of the nitride layer may be between about 10 nm to 50 nm. The material of the photoresist layer can be a material of alkene monomer, a material containing nitrine quinine compounds or a material of polyethylene laurate, etc. Except for the photoresist layer, the layers in the above-mentioned multi-layered structure may be formed in sequence on the SOI layer 100 by means of Chemical Vapor Deposition (CVD), High Density Plasma CVD, Atomic Layer Deposition (ALD), Plasma Enhanced Atomic Layer Deposition (PEALD), Pulsed Laser Deposition (PLD) or other appropriate methods. After patterning the photoresist layer, the multi-layered structure may be etched to form the gate structure 200 as shown in FIG. 3 (a gate line is formed on the SOI substrate).

In a gate-last process, the gate structure 200 comprises a dummy gate and a gate dielectric layer carrying the dummy gate. A replacement gate process may be performed in the subsequent steps to remove the dummy gate so as to form the desired gate stack structure.

Usually, sidewall spacers 210 may be formed on both sides of the gate structure 200 so as to separate the gate structure 200 after forming the gate structure 200. The sidewall spacer 210 may be formed of silicon nitride, silicon oxide, silicon oxynitride, silicon carbide and/or other appropriate materials. The sidewall spacer 210 may have a multi-layered structure. The sidewall spacer 210 may be formed by a deposition-etching process, and the thickness of the sidewall spacer is within the range of about 10 nm to 100 nm.

Referring to FIG. 4, step S102 is performed to etch the SOI layer 100 and the BOX layer 110 of the SOI substrate on both sides of the gate structure 200, thereby forming a trench 140 exposing the BOX layer 110. The trench 140 at least partially enters into the BOX layer 110. Specifically, the SOI layer 100 on both sides of the gate structure 200 is removed first using an appropriate etching process, then a part of the exposed BOX layer 110 is removed to form the trench 140, thus the trench 140 not only exposes the remaining part of the BOX layer 110, and spatially and partially replaces the un-etched BOX layer 110, but also partially enters into the BOX layer 110. The depth of the trench 140 is a sum of the thickness of the SOI layer 100 that is etched away and the thickness of the BOX layer 110 that is etched away. With respect to the SOI substrate used in this specific embodiment, the thickness of the BOX layer 110 is greater than about 100 nm, the thickness of the ultrathin SOI layer is about 20 nm-30 nm, so the depth of the trench 140 is within the range of about 50 nm-150 nm. Since the trench 140 will be filled in Step S103 to be a semiconductor layer that is ready for forming the source/drain region, for the sake of enlarging the source/drain region, all of the SOI layer 100 and parts of the BOX layer 110 between the gate structure 200 and the isolation region 120 may be etched, as shown in FIG. 4. The formed trench 140 exposes a part of the isolation region 120, so the area of the filled semiconductor layer is larger.

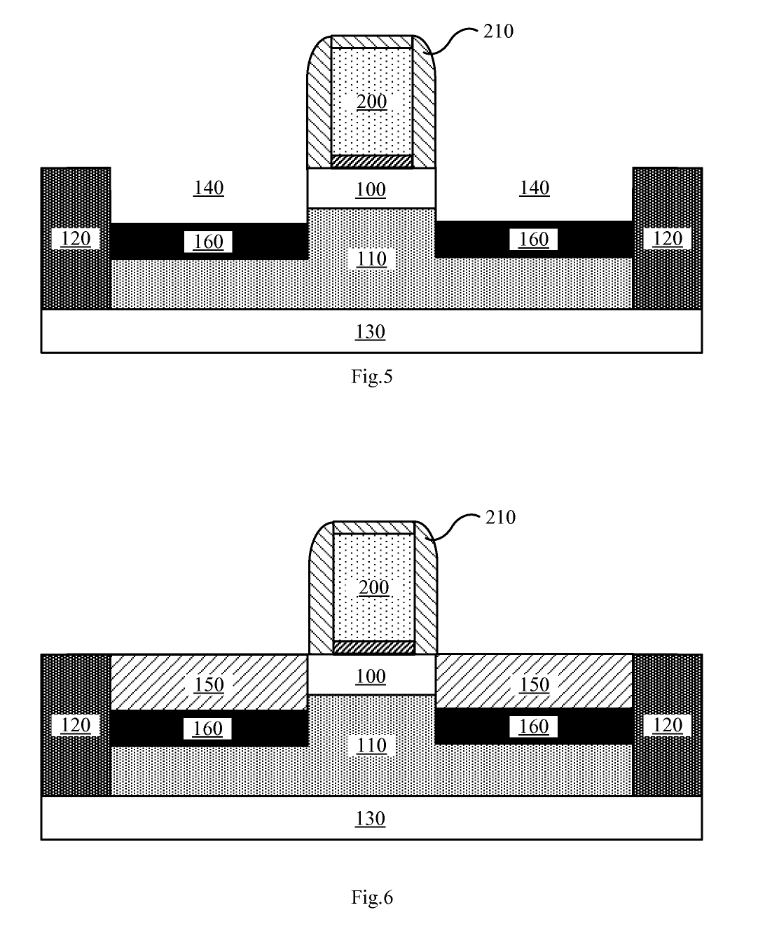

Referring to FIG. 5, step S103 is performed to form a stressed layer 160 that fills up a part of the trench 140. The material of the stressed layer 140 is usually silicon nitride. The stressed layer 160 may be formed in the trench 140 by means of Chemical Vapor Deposition (CVD), High Density Plasma CVD, Atomic Layer Deposition (ALD), Plasma Enhanced Atomic Layer Deposition (PEALD), Pulsed Laser Deposition (PLD) or other appropriate methods. The stressed layer 140 does not fully fill up the trench 140, that is, the upper surface of the stressed layer 140 is lower than the lower surface of the gate structure 200 (in this embodiment, the upper surface of the stressed layer 140 is lower than the lower surface of the gate dielectric layer of the gate structure 200).

Referring to FIG. 6, step S104 is performed to form a semiconductor layer 150 covering the stressed layer 160 in the trench 140. Preferably, after forming the semiconductor layer 150, the semiconductor layer 150 is planarized by performing Chemical Mechanical Polishing (CMP), so that the upper surface of the semiconductor layer 150 is flush with the lower surface of the gate structure 200 (the wording “flush with” in this invention refers to that the height difference therebetween is within the allowable range of the process error). The material of the semiconductor layer 150 may be one of polysilicon, amorphous silicon, silicon-germanium and amorphous silicon-germanium, or any combination thereof. Alternatively, the method shown in FIG. 1(a) further comprises a step S105 of forming a source/drain region in the semiconductor layer 150. The source/drain region may be formed by implanting P type or N type dopants or impurities into the semiconductor layer 150. For example, for a PMOS device, the source/drain region may be a P-doped SiGe, and for a NMOS device, the source/drain region may be N-doped Si. The source/drain region may be formed by a method including photoetching, ion-implantation, diffusion and/or other appropriate processes.

In the embodiment shown in FIGS. 3-6, the sidewall spacers 210 are formed before the formation of the trench 140. When the trench 140 is formed, the sidewall spacers 210 protect the SOI layer 100 and the BOX layer 110 thereunder from being etched, so in the semiconductor structure shown in FIG. 4, the sidewall of the trench 140 that is close to the sidewall spacers 210 terminates at the level that is flush with the sidewall spacer 210.

According to another specific embodiment of the present invention, the trench 140 is formed first, then the stressed layer 160 and the semiconductor layer 150 are formed in sequence, and finally the sidewall spacers 210 are formed on both sides of the gate structure 200. So the sidewall of the trench 140 that is close to the gate structure 200 terminates at the level that is flush with the sidewall of the gate structure 200. Namely, a part of the semiconductor layer 150 is under the sidewall spacers 210, thereby enlarging the area of the semiconductor layer 150.

Referring to FIG. 1(b), which is a flow chart of another specific embodiment of the method for manufacturing the semiconductor structure according to the present invention. The method comprises:

step S201: providing an SOI substrate and covering the SOI substrate with a mask, the area covered by the mask being the area that is predetermined for forming a gate line;
step S202: etching a SOI layer and a BOX layer of the SOI substrate on both sides of the mask to form a trench exposing the BOX layer, the trench partially entering into the BOX layer;
step S203: forming a stressed layer that fills up a part of the trench;
step S204: forming a semiconductor layer covering the stressed layer in the trench; and
step S205: removing the mask to expose the area covered by the mask and forming a gate structure on the area.

The steps S201 to S205 will be described below with reference to FIGS. 7-9. FIGS. 7-9 are schematic cross-sectional views of the various manufacturing stages of the semiconductor structure during the process for manufacturing the semiconductor structure following the flow as shown in FIG. 1(b) according to one specific embodiment of the present invention. It shall be noted that the drawings for each of the embodiments of the present invention are only schematic, and thus are not drawn to scale.

The difference between the method shown in FIG. 1(b) and the method shown in FIG. 1(a) is in that, in the process shown in FIG. 1(a), a gate structure is formed first on the substrate, then a trench is formed by etching, and then the trench is filled to form the stressed layer and the semiconductor layer; while in the process shown in FIG. 1(b), a mask is formed first on the substrate to cover the area on which the gate structure is to be formed, then as in the steps in FIG. 1(a), the trench is formed by etching, and then the trench is filled to form the stressed layer and the semiconductor layer, and a different step is that finally the mask is removed and the gate structure is formed at the area where the mask is removed.

The steps of forming the mask and removing the mask will be specifically described below, while as for the steps that are the same as those in the process shown in FIG. 1(a), reference can be made to the relevant description in the above embodiment, and they will not be repeated here.

As shown in FIG. 7, the SOI substrate is covered with a mask 400, and usually a photoresist is used as the mask. Then, the photoresist mask is patterned by a photoetching process. The patterned photoresist mask is used to form a desired shape (i.e., a shape of the gate line in the present invention) by an etching process.

Next, a trench 140 is formed by etching. The depth of the trench 140 may be within the range of about 50 nm to 150 nm. The trench 140 exposes a part of the isolation region 120 of the SOI substrate.

As shown in FIG. 8, a part of the trench 140 is filled to form a stressed layer 160, and then a semiconductor layer 150 covering the stressed layer 160 is formed. The material of the stressed layer 160 includes silicon nitride. The material of the semiconductor layer 150 includes one of polysilicon, amorphous silicon, silicon-germanium and amorphous silicon-germanium, or any combination thereof. The mask is removed after forming the semiconductor layer 150. Alternatively, the upper surfaces of the semiconductor 150, the SOI layer 100 and the isolation region 120 may be flush with each other by means of a planarization processing.

As shown in FIG. 9, a gate structure 200 is formed at the previously mentioned area covered by the mask. Alternatively, sidewall spacers 210 may be formed on both sides of the gate structure 200. Alternatively, a source/drain region may further be formed in the SOI substrate.

In the semiconductor structure and the method for manufacturing the same according to the present invention, a trench is formed on an ultrathin SOI substrate, first filled with a stressed layer, and then filled with a semiconductor material to be ready for forming a source/drain region. The stressed layer provides a favorable stress to the channel of the semiconductor device, thus facilitating improving the performance of the semiconductor device.

Although the exemplary embodiments and the advantages thereof have been described in detail, it shall be understood that various changes, substitutions and modifications can be made to these embodiments without departing from the spirit of the present invention and the protection scope defined by the attached claims. As for other examples, it shall be easily understood by those skilled in the art that the sequences of the process steps can be changed within the protection scope of the present invention.

In addition, the scope to which the present invention is applied is not limited to the process, mechanism, manufacture, material composition, means, methods and steps described in the specific embodiments in the specification. Those skilled in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods, or steps.

1. A method for manufacturing a semiconductor structure, comprising:
a) providing an SOI substrate and forming a gate structure (200) on said SOI substrate;
b) etching a SOI layer (100) and a BOX layer (110) of said SOI substrate on both sides of said gate structure (200) to form a trench (140) exposing the BOX layer (110), said trench (140) partially entering into the BOX layer (110);
c) forming a stressed layer (160) by filling up a part of said trench (140); and
d) forming a semiconductor layer (150) to cover the stressed layer (160) in the trench (140).

2. A method for manufacturing a semiconductor structure, comprising:
a) providing an SOI substrate and covering a part of said SOI substrate with a mask (400), the part of said SOI substrate covered by the mask being the area that is predetermined for forming a gate line;
b) etching a SOI layer (100) and a BOX layer (110) of said SOI substrate on both sides of said mask (400) to form a trench (140) exposing the BOX layer (110), said trench (140) partially entering into the BOX layer (110);
c) forming a stressed layer (160) by filling up a part of said trench (140);
d) forming a semiconductor layer (150) to cover the stressed layer (160) in the trench (140); and
e) removing the mask to expose the part of said SOI substrate covered by the mask and forming a gate structure (200) thereon.

3. The method according to claim 1, further comprising forming sidewall spacers (210) on both sides of the gate structure (200) after forming the gate structure (200).

4. The method according to claim 1, wherein the depth of the trench (140) is within the range of about 50 nm to 150 nm.

5. The method according to claim 1, wherein the trench (140) exposes a part of an isolation region (120) of the SOI substrate.

6. The method according to claim 1, wherein the material of the semiconductor layer (150) includes one of polysilicon, amorphous silicon, silicon-germanium and amorphous silicon-germanium, or any combination thereof.

7. The method according to claim 1, wherein the material of the stressed layer (160) includes silicon nitride.

8. The method according to claim 1, further comprising: f) forming a source/drain region in the semiconductor layer (150).

9. A semiconductor structure comprising an SOI substrate, a gate structure (200), a stressed layer (160) and a semiconductor layer (150), wherein
the SOI substrate includes a SOI layer (100) and a BOX layer (110); the gate structure (200) is formed on the SOI layer (100);
the stressed layer (160) is formed in the SOI substrate on both sides of the gate structure (200) to contact the BOX layer (110) and extend into the BOX layer (110), and the upper surface of the stressed layer (160) is lower than the lower surface of the gate structure (200);
and the stressed layer (160) is covered by the semiconductor layer (150) and the semiconductor layer (150) is in contact with the SOI layer (100).

10. The semiconductor structure according to claim 9, further comprising sidewall spacers (210) formed on both sides of the gate structure (200).

11. The semiconductor structure according to claim 9, wherein the thickness of the semiconductor layer (150) is within the range of about 50 nm to 150 nm.

12. The semiconductor structure according to claim 9, wherein the semiconductor layer (150) and the stressed layer (160) are also in contact with an isolation region (120) of the SOI substrate.

13. The semiconductor structure according to claim 9, wherein the material of the semiconductor layer (150) includes one of polysilicon, amorphous silicon, silicon-germanium and amorphous silicon-germanium, or any combination thereof.

14. The semiconductor structure according to claim 9, wherein the material of the stressed layer (160) includes silicon nitride.

15. The semiconductor structure according to claim 9, wherein a source/drain region is provided in the semiconductor layer (150).

16. The method according to claim 2, further comprising forming sidewall spacers (210) on both sides of the gate structure (200) after forming the gate structure (200).
